(19) United States
(12) Patent Application Publication
(10) Pub. No.: US 2006/0187735 A1
(43) Pub. Date: Aug. 24, 2006

(54) Indexation by transposition of matrix of large dimension

(75) Inventor: Edmond Lassalle, Lannion (FR)

Correspondence Address: LOWE HAUPTMAN BERNER, LLP, 1700 DIAGONAL ROAD, SUITE 300, ALEXANDRIA, VA, 22314, US

(73) Assignee: FRANCE TELECOM, Paris (FR)

(21) Appl. No.: 11/322,659

(22) Filed: Jan. 3, 2006

(30) Foreign Application Priority Data
Jan. 4, 2005 (FR) 0500055

(51) Int. Cl. G11C 8/00

(52) U.S. Cl. 365/230.01

(57) ABSTRACT

A data processing system comprises a first memory and a second memory including a sparse direct matrix comprising full boxes storing a data item and a column index and addressable consecutively. A module dimensions a transposed matrix, by reading row by row column indices of the direct matrix so as to reserve boxes of the transposed matrix in the second memory. A module identifies in the first memory a submatrix of reserved boxes of the transposed matrix and occupying a memory space smaller than the first memory. A module fills in the boxes of the submatrix according to the column indices read from the boxes of the direct matrix, and transfers the submatrix into the second memory to fill-in the transposed matrix.

### RELATED APPLICATIONS

The present application is based on, and claims priority from, French Application Number 0500055, filed Jan. 4, 2005, the disclosure of which is hereby incorporated by reference herein in its entirety.

### BACKGROUND OF THE INVENTION

1. Field of the Invention

The present invention relates to a method of indexation by transposition of matrix of large dimension. More particularly it deals with a fast method of indexation with each new element to be indexed.

2. Description of the Prior Art

Although the central memory of an data processing system is ordered sequentially, the representation of a matrix with L rows and C columns and its addressing do not pose any problem when all the elements of the matrix are respectively associated with boxes in memory according to a matrix representation referred to as a “full” matrix. Each row [L] (or column) of the matrix contains matrix elements, called as first elements, and each column [C] (or row) of the matrix contains matrix elements, called as second elements. The switch from a two-dimensional representation [L, C] corresponding to the matrix to a one-dimensional representation corresponding to the central memory comprises an arranging of the boxes of each row of the matrix in central memory in a contiguous manner and storage of the entire matrix by contiguous storage of the rows of the matrix. Thus, knowing the dimensions of the matrix [L, C], a simple shift makes it possible to access any box of the matrix.

For example in a document base, the indexation of documents corresponds to a matrix match between on the one side the set of documents in the guise of first elements and on the other a set of words appearing in the documents in the guise of second elements. This match is represented in the form of a matrix [words, documents]. Each box of this matrix includes a data item indicating the presence or the absence of a word in a document. In practice, on account of the high number of documents to be indexed, for example 10 000 to a few giga and of the size of the vocabulary, for example 20 000 to a million, a full-matrix representation is not conceivable.

A sparse-matrix representation comprising boxes storing only “meaningful” data, so-called full boxes, is more suitable. The absence of words being more frequent than the presence of words within each document, an economical sparse-matrix representation can consist in keeping in memory only the boxes indicating the presence of words in the document, that is to say the full boxes.

However, the sparse-matrix representation favors only a mode of access to the central memory by entire row exclusively or by entire column exclusively, as opposed to the full-matrix representation which allows undifferentiated access either by entire row or by entire column. In the above example of the document base, access to the central memory exclusively by row or by column causes difficulty in the reciprocal determination of all the documents which contain a given word and of all the words appearing in a given document. Specifically, the central memory stores exclusively either each document as a file containing a string of words, this storage also being called a direct-file representation, or each word as a list identifying the documents which contain this word, called an inverse-file representation.

Other methods of indexation are based on hash tables. A hash table is an association table with a single key whose number of box is fixed and whose boxes are accessible indirectly via an integral hash value of the key. A hash function h respectively associates integral hash values with keys. A key is ranked with the rank h(key) in the table. The drawback of this indexation is that several keys may be associated with the same integral value by the hash function h, thus entailing a clash and the deletion of one of the two keys. In a document base indexed by a hash table, the clash of keys induces a loss of nearly ten percent of the indexed documents. It is possible to use a clashless hash table. In case of an identical key, the new key is used in a hash subtable and so on and so forth until a unique new key is obtained. A clashless hash table is more expensive in terms of memory space and length of key. Furthermore, an undifferentiated global view of the documents and of the words is rendered difficult by such indexation. Another drawback is induced by the entry of new documents to be indexed which gives rise to a significant time for updating the indexation of all the elements stored and to be stored in the hash table.

### OBJECTS OF THE INVENTION

An object of the invention is to index in a global and undifferentiated manner first elements to second elements and vice versa by creating an inverse file for indexation on the basis of a direct indexation file.

An object of the invention is to speedily update the indexation of new elements as soon as they are entered into a memory of high capacity with relatively slow write-read access.

### SUMMARY OF THE INVENTION

To achieve these objects, a method of indexation is performed in a data processing system that comprises a first memory and a second memory including a sparse direct matrix that only has full boxes and arises from a matrix of full and empty boxes. The boxes of the direct matrix each store an associated data item and an associated column index. The method includes the steps of:

dimensioning row by row a matrix which is the transpose of the direct matrix, by reading row by row column indices of the direct matrix so as to reserve as many boxes for each row of the transposed matrix in the second memory as a number of occurrences of a respective column index in the direct matrix;

identifying in the first memory a submatrix of reserved boxes forming together with other consecutive submatrices the transposed matrix, each submatrix occupying a memory space smaller than the size of the first memory;

filling in the boxes of the submatrix in the first memory with data associated with column indices read from the boxes of the direct matrix in the second memory and that are identical to row indices of the transposed matrix that relate to rows included in the submatrix;

transferring the filled-in submatrix from the first memory to the second memory so as to fill in the transposed matrix; and

iteratively repeating the preceding three steps for each of the submatrices of the transposed matrix.

Within the meaning of the invention and according to the reciprocity of the matrices, the rows may be columns and the columns may be rows.

The method of the invention creates a transposed matrix on the basis of a direct matrix so as to index first elements to second elements and to obtain a global view of said elements when searching for a first element or for a second element.

The method of the invention has the advantage of being applicable to matrices of large dimensions.

According to the method, each submatrix includes one or more complete rows of the transposed matrix. The boxes reserved in a row of the transposed matrix are addressable as a function of a row index of the transposed matrix which is identical to a column index read from boxes of the direct matrix.

The invention also relates to a data processing system for performing a method of indexation, said system comprising a first memory and a second memory including a sparse direct matrix that only has full boxes and arises from a matrix of full and empty boxes, the boxes of the direct matrix storing an associated data item and an associated column index. The system includes a processor for:

(1) dimensioning row by row a matrix which is the transpose of the direct matrix, by reading row by row column indices of the direct matrix so as to reserve as many boxes for each row of the transposed matrix in the second memory as a number of occurrences of a respective column index in the direct matrix;

(2) identifying in the first memory a submatrix of reserved boxes forming together with other consecutive submatrices the transposed matrix, each submatrix occupying a memory space smaller than the size of the first memory; and

(3) filling in the boxes of the submatrix in the first memory with data associated with column indices read from the boxes of the direct matrix in the second memory and that are identical to row indices of the transposed matrix that relate to rows included in the submatrix so as to transfer the filled-in submatrix from the first memory to the second memory.

The method of the invention takes one to two minutes to determine the transposed matrix as a function of the direct matrix as soon as new elements are entered. The transposed matrix is constructed progressively in the first memory, such as a processor central memory, thus allowing faster discontinuous access than in the second memory which is preferably a high-capacity storage peripheral, for example a hard disk. The direct matrix, for its part, is read continuously from the second memory allowing faster processing.

Finally, the invention pertains to a storage arrangement of a computer program adapted to be executed on the data processing system, said program comprising instructions suitable for the implementation of the method of indexation by matrix transposition which, when the program is loaded and executed on said data processing system, carry out the steps of the method of the invention.

### BRIEF DESCRIPTION OF THE DRAWINGS

Other features and advantages of the invention will be apparent more clearly from the reading of the following description of several preferred embodiments of the invention, given by way of nonlimiting examples and with reference to the corresponding appended drawings in which:

FIG. 1 is a schematic block diagram of a data processing system implementing the method of the invention;

FIG. 2 shows a full direct matrix;

FIG. 3 shows a full transposed matrix;

FIG. 4 shows a transformation of a sparse direct matrix in a sparse transposed matrix in relation to the matrices according to FIGS. 2 and 3; and

FIG. 5 is an algorithm of the method of indexation according to the invention.

To index first elements to second elements and vice versa, the invention creates on the basis of a direct file, also termed the direct matrix, storing the first elements with respect to the second elements an inverse file, termed the matrix transpose of the direct matrix, the inverse file storing the second elements with respect to the first elements.

### DESCRIPTION OF THE PREFERRED EMBODIMENTS

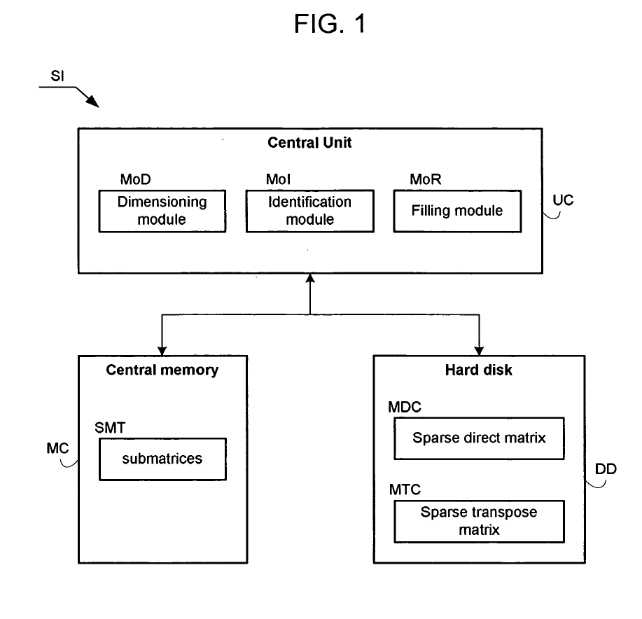

With reference to FIG. 1, the data processing system SI implements the method of indexation of the invention. The data processing system SI is for example a computer of database management server type interrogatable through a telecommunications network so as to search for digital documents as a function of a query including words with the aid of a matrix that is transposed according to the invention after having analyzed and classed the documents as a function of the words according to a direct matrix. The data processing system SI comprises a central processing unit UC, such as a processor, controlling the execution of the method of indexation and linked by a bus to first and second memories. The first memory is a central memory MC of the system, such as a nonvolatile EEPROM memory recording instructions and data. The second memory is a storage peripheral comprising a recorded medium such as a hard disk DD, and having a capacity markedly greater than that of the first memory MC and whose write-read discontinuous access is not as fast as that of the first memory. The hard disk DD initially contains a matrix termed the sparse direct matrix MDC subsequently in the description, illustrated in FIG. 4. The sparse direct matrix arises from a full direct matrix MDP comprising L rows and C columns.

The central unit UC creates, determines and records a sparse transposed matrix MTC on the basis of the sparse direct matrix MDC in the hard disk DD. On account of their significant size, the sparse matrices MDC and MTC are not stored in the central memory MC but in the hard disk DD. However, the transformation of the matrix MDC into the matrix MTC by the central unit UC comprises discontinuous accesses to the rows of the matrices in the hard disk, this being very penalizing in terms of processing time. Specifically, the technology of hard disks favors sequential reading and writing. To optimize the processing time, sequential accesses row by row are performed for a continuous reading of the direct matrix MDC and a partial continuous writing of the transposed matrix MTC onto the hard disk DD. To write the whole of the transposed matrix MTC in a discontinuous manner, the central unit progressively splits the latter into submatrices SMT which are formed one after the other in the central memory MC.

To transform the direct matrix MDC into the transposed matrix MTC, the central unit UC comprises a dimensioning module MoD for dimensioning the matrix MTC, an identification module MoI for identifying submatrices SMT forming the matrix MTC and a filling module MoR for filling in the boxes of the submatrices SMT. These three modules are functional software modules detailed subsequently in the description.

In a general manner, a full matrix is represented by first lines, rows or columns, defined by first indices and by second lines, columns or rows, defined by second indices. The intersection of each of the first lines with each of the second lines forms full or empty boxes.

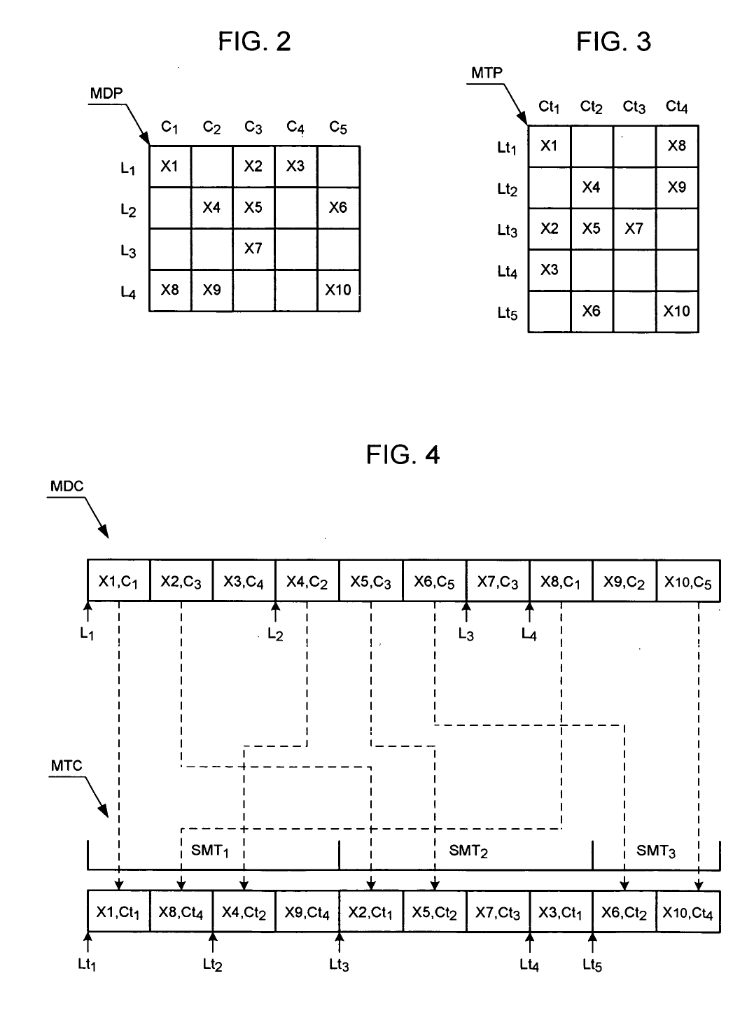

With reference to exemplary matrices with 20 boxes shown in FIGS. 2 and 3, rows L₁ to L₄ in the guise of first lines of a full direct matrix MDP of dimension 4×5 comprise first elements and the columns C₁ to C₅ in the guise of second lines comprise second elements. Each full box of the matrix MDP comprises a data item X. Conversely to the representation of the full direct matrix, rows Lt₁ to Lt₅ in the guise of first lines of the full transposed matrix MTP of dimension 5×4 resulting from the transposition of the matrix MDP comprise the second elements and the columns Ct₁ to Ct₄ in the guise of second line of the matrix MTP comprise the first elements. The full direct matrix MDP and the full transposed matrix MTP have the same number of box storing the same data.

The sparse direct matrix MDC, illustrated in FIG. 4 and recorded in the hard disk DD, arises from the full direct matrix MDP represented in FIG. 2 and comprises only full boxes and hence does not comprise any empty box. The boxes of the sparse matrix MDC are addressed consecutively in the hard disk DD and form consecutive rows in the guise of first lines of the sparse matrix by reading of the full boxes of the rows of the full direct matrix MDP, skipping the empty boxes. Each box of the sparse matrix MDC thus stored contains a data item, for example X1 and a column index, also called second-line index, for example C₁, corresponding to the index of the column of the full direct matrix MDP containing the said data item. Thus, during continuous reading of the sparse direct matrix MDC, the central unit UC shifts a pointer in the hard disk to successively access row by row the boxes of the said sparse direct matrix. This shift is also implemented for continuous writing of the sparse transposed matrix MTC to the hard disk.

In a reciprocal manner, to consecutively form the columns of the sparse matrix, the boxes of the sparse matrix MDC are addressable consecutively in memory by reading of the full boxes of the columns of the full direct matrix MDP. Each box of the sparse matrix MDC thus stored contains a data item and a row index corresponding to the row index of the full direct matrix MDP containing the said data item.

In the subsequent description, reference is made to the first row-wise representation shown in FIG. 4.

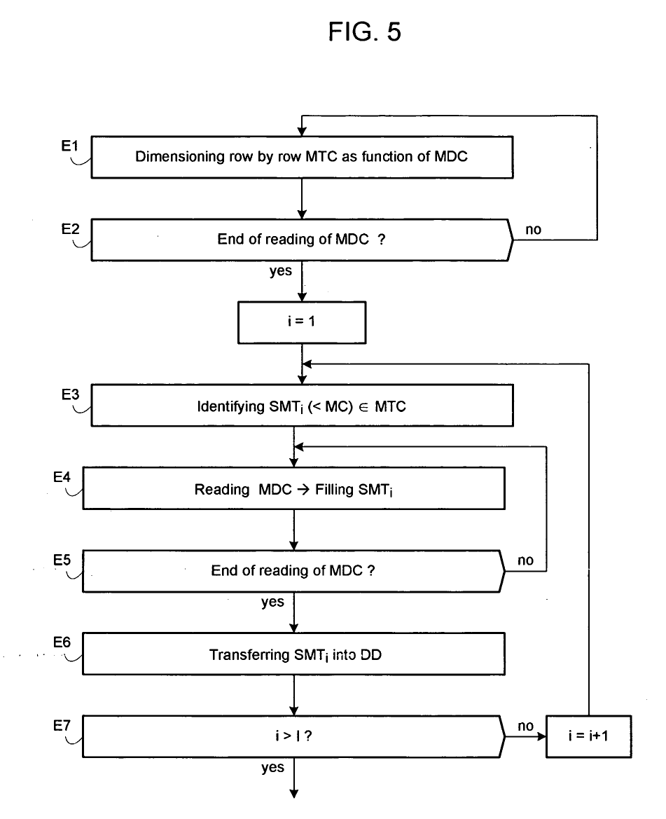

As shown in FIG. 5, the method of indexation by matrix transposition according to the invention comprises steps E1 to E7. The hard disk DD of the data processing system S1 has initially recorded the sparse direct matrix MDC stored as illustrated according to the example of FIG. 4. Characteristics of the sparse direct matrix MDC, such as the number of rows L and the number of columns C thereof, are therefore initially recorded in the hard disk and readable by the central unit.

In the first step E1, the dimensioning module MoD of the central unit UC dimensions row by row the matrix transpose MTC of the direct matrix MDC as a function of the characteristics of the direct matrix MDC. The dimensioning consists for each row of the transposed matrix in searching for a column index identical to the index of the said row of the transposed matrix by continuously reading row by row all the boxes of the direct matrix MDC stored in the hard disk DD. For each index of column C read, the dimensioning module MoD counts the number of occurrence of this column index in the direct matrix MDC and dimensions a row of the transposed matrix MTC by reserving in the hard disk DD as many boxes as the number of occurrence of column index. All the boxes of the dimensioned row of the transposed matrix MTC are addressable by a row index Lt of the transposed matrix which is equal to the column index C of the direct matrix MDC, the number of rows Lt of the transposed matrix MTC, for example 5, being identical to the number of columns C of the direct matrix MDC.

For example referring to FIG. 4, on reading the first box of the direct matrix MDC including the column index C₁, the dimensioning module MoD reserves in the hard disk DD a box addressable as a function of the row index Lt₁ of the transposed matrix MTC and sets a box count to 1 for the first row Lt₁ of the transposed matrix. Subsequently, during readings of the first box of the row L₄ in the matrix MDC, the module MoD reserves one more box for the row Lt₁ of the matrix MTC and the count for the row Lt₁ is equal to the dimension 2 of the row Lt₁. Following the reading of the first box of the direct matrix MDC, the dimensioning module reads the second box of the direct matrix MDC comprising the column index C₃, reserves in the hard disk DD a box addressable as a function of the row index Lt₃ of the transposed matrix MTC MTC and sets a box count to 1 for the third row Lt₃ of the transposed matrix. Subsequently, during readings of the second box of the row L₂ and of the box of the row L₃ in the matrix MDC, the module MoD reserves two more boxes for the row Lt₃ of the matrix MTC and the count for the row Lt₃ is equal to the dimension 3 of the row Lt₃.

Once all the boxes of the direct matrix MDC are read in step E2, the rows Lt of the transposed matrix MTC are all dimensioned and reserved in the hard disk DD. The central unit then iteratively repeats I times a set of steps E3 to E7.

In step E3, the identification module MoI of the central unit UC identifies as a function of the size of the central memory MC a submatrix of reserved boxes SMTᵢ which together with other consecutive submatrices identified iteratively SMT₁ to SMT₁ forms the transposed matrix MTC, with 1≦i≦I and I the total number of submatrices making up the matrix MTC. Each submatrix SMTᵢ has a dimension such that it occupies a predetermined memory space smaller than the size of the central memory MC, preferably substantially equal to the size of the central memory, and includes at least one complete row and more generally consecutive complete rows of the transposed matrix MTC.

FIG. 4 represents an exemplary transposed matrix MTC formed by three submatrices SMT₁, SMT₂ and SMT₃. The dimensions of the submatrices may be different, are at least equal to the smallest dimension of the rows of the transposed matrix MTC determined in step E2, and are respectively equal to the sum of dimensions, that is to say the sum of numbers of boxes in entire rows of the transposed matrix MTC, while remaining smaller than the number of boxes that the central memory can contain. The addresses of the boxes of each submatrix SMTᵢ are bounded by the smallest and the largest of the successive indices of the rows of the submatrix, which indices may possibly be merged when the submatrix comprises just one row. For example in FIG. 4, the addresses of the boxes of the submatrix SMT₁ are bounded by the indices 1 and 2 of the rows Lt₁ and Lt₂. A box of the transposed matrix MTC is processed in central memory MC if it is addressed as a function of a row Lt index lying between the two row indices bounding the submatrix SMT. The indices of rows Lt defining the submatrix SMT in the transposed matrix MTC correspond to indices of columns C in the direct matrix MD.

After the identification module has provided a memory space for the current identified submatrix of reserved boxes SMTᵢ in the central memory MC, the filling module MoR of the central unit UC fills in the boxes of the submatrix SMTᵢ in step E4, by continuous reading of the data in the successive boxes of the direct matrix MDC recorded in the hard disk DD and by discontinuous but ordered writing into the corresponding reserved boxes of the submatrix SMTᵢ in the central memory MC of the data read and of column indices Ct of the submatrix SMTᵢ. For each box of each row L of the direct matrix MDC, if the column index C of the direct matrix MDC is identical to the index of a row Lt of the transposed matrix which is an index relating to a row included in the identified submatrix SMTᵢ, then the filling module MoR stores in a box of the row Lt of the submatrix SMTᵢ the data item X associated with the column index C read from the box of the direct matrix and also stores in this box a column index Ct identical to the index of the row L of the matrix MDC including the box which is read by the module MoR.

For example in conjunction with FIG. 4, the identified submatrix SMTᵢ is the identified submatrix SMT₁ in the central memory MC and comprising four boxes. On continuous reading of the boxes of the direct matrix MDC, the filling module MoR identifies the column index C₁ of the first box of the row L of the matrix MDC as lying between the row indices Lt₁ and Lt₂ of the submatrix SMT₁. The filling module MoR stores in the first box of the row Lt₁ of the submatrix SMT₁ the data item X1 associated with the column index C₁ and the column index Ct₁ identical to the row index L₁ of the matrix MDC. On reading of the second box of the direct matrix MDC, the filling module identifies the column index C₃ as not lying between the row indices Lt₁ and Lt₂ of the submatrix SMT₁, and does not store the column index C₃. At the end of the reading of the direct matrix MDC, all the four boxes of the submatrix SMT₁ are filled in. Each box of the submatrix SMT₁ once filled in comprises a data item X and a column index Ct.

At the end, step E5, of the reading of the direct matrix MDC, the filling module MoR transfers the filled-in submatrix SMTᵢ into the hard disk DD, in step E6.

A following submatrix SMTᵢ₊₁ which comprises reserved boxes and is contiguous with the preceding submatrix SMTᵢ in the matrix MTC is thereafter identified by the identification module MoI in the central memory MC so as to be filled in there by the filling module MoR. Steps E3 to E6 are iteratively repeated in step E7, until the total writing and the recording of the transposed matrix MTC in the hard disk DD. The transposed matrix MTC recorded in the hard disk DD comprises as many boxes as the direct matrix MDC also recorded on the hard disk DD.

The invention described here relates to a method and a data processing system for indexation by transposition of matrix of large dimension. According to a preferred implementation, the steps of the method are determined by the instructions of a program incorporated into in memory of the central unit of the data processing system such as the data server or a computer. The program comprises program instructions which, when the said program is loaded and executed in the data processing system, operation of which is then controlled by the execution of the program, carry out the steps of the method according to the invention.

Consequently, the invention applies also to a computer program, in particular a computer program on or in an information medium, suitable for implementing the invention. This program may use any programming language whatsoever, and be in the form of source code, object code, or of code intermediate between source code and object code such as in a partially compiled form, or in any other desirable form whatsoever for implementing the method according to the invention.

The information medium may be any entity or device whatsoever capable of storing the program. For example, the medium can comprise a storage means, such as a ROM, for example a CD ROM or a microelectronic circuit ROM, or else a magnetic recording means, for example a diskette (floppy disk) or a hard disk.

Moreover, the information medium may be a transmissible medium such as an electrical or optical signal, which may be conveyed via an electrical or optical cable, by radio or by other means. The program according to the invention may in particular be downloaded onto an Internet-type network.

Alternatively, the information medium may be an integrated circuit in which the program is incorporated, the circuit being suitable for executing or for being used in the execution of the method according to the invention.

What I claim is:

1. A method of indexation in a data processing system that comprises a first memory and a second memory including a sparse direct matrix that only has full boxes and arises from a matrix of full and empty boxes, said boxes of said direct matrix each storing an associated data item and an associated column index, said method including the steps of:
dimensioning row by row a matrix which is the transpose of said direct matrix, by reading row by row column indices of said direct matrix so as to reserve as many boxes for each row of said transposed matrix in said second memory as a number of occurrences of a respective column index in said direct matrix;
identifying in said first memory a submatrix of reserved boxes forming together with other consecutive submatrices said transposed matrix, each submatrix occupying a memory space smaller than the size of said first memory;
filling in the boxes of said submatrix in said first memory with data associated with column indices read from said boxes of said direct matrix in said second memory and that are identical to row indices of said transposed matrix that relate to rows included in said submatrix;
transferring the filled-in submatrix from said first memory to said second memory so as to fill in said transposed matrix; and
iteratively repeating the preceding three steps for each of the submatrices of said transposed matrix.

2. A method as claimed in claim 1, wherein each submatrix includes at least one complete line of said transposed matrix.

3. A method as claimed in claim 1, wherein said boxes reserved in a row of said transposed matrix are addressable as a function of a row index of said transposed matrix which is identical to a column index read from boxes of said direct matrix.

4. A method as claimed in claim 1, wherein during the filling in of a submatrix of said transposed matrix and for each read box of each row of said direct matrix, if the column index of said direct matrix is identical to the index of a row of said transposed matrix that relates to a row included in said submatrix, then the data item associated with the column index read from said box of said direct matrix and a column index identical to said index of the row including said read box are stored in a box of the row of said submatrix.

5. A data processing system for the implementation of a method of indexation, said data processing system including:
a first memory and a second memory including a sparse direct matrix that only has full boxes and arises from a matrix of full and empty boxes, said boxes of said direct matrix storing an associated data item and an associated column index;
a processor arrangement for: (a) dimensioning row by row a matrix which is the transpose of the direct matrix, by reading row by row column indices of said direct matrix so as to reserve as many boxes for each row of said transposed matrix in the second memory as a number of occurrences of a respective column index in said direct matrix;
(b) identifying in said first memory a submatrix of reserved boxes forming together with other consecutive submatrices said transposed matrix, each submatrix occupying a memory space smaller than the size of said first memory; and
(c) filling in the boxes of said submatrix in said first memory with data associated with column indices read from said boxes of said direct matrix in said second memory and that are identical to row indices of the transposed matrix that relate to rows included in said submatrix so as to transfer the filled-in submatrix from said first memory to said second memory.

6. A data processing system as claimed in claim 5, wherein said first memory is a processor central memory and said second memory is a storage peripheral.

7. A storage element storing a computer program adapted to be executed on a data processing system that comprises a first memory and a second memory including a sparse direct matrix that only has full boxes and arises from a matrix of full and empty boxes, said boxes of said direct matrix each storing an associated data item and an associated column index, said computer program comprising instructions suitable for the implementation of the method of indexation by matrix transposition which, when the program is loaded and executed on said data processing system, carry out the steps of:
dimensioning row by row a matrix which is the transpose of said direct matrix, by reading row by row column indices of said direct matrix so as to reserve as many boxes for each row of said transposed matrix in said second memory as a number of occurrences of a respective column index in said direct matrix;
identifying in said first memory a submatrix of reserved boxes forming together with other consecutive submatrices said transposed matrix, each submatrix occupying a memory space smaller than the size of said first memory;
filling in the boxes of said submatrix in said first memory with data associated with column indices read from said boxes of said direct matrix in said second memory and that are identical to row indices of said transposed matrix that relate to rows included in said submatrix;
transferring the filled-in submatrix from said first memory to said second memory so as to fill in said transposed matrix; and
iteratively repeating the preceding three steps for each of the submatrices of said transposed matrix.
